(19) United States
(12) Patent Application Publication
(10) Pub. No.: US 2007/0197034 A1
(43) Pub. Date: Aug. 23, 2007

(54) Semiconductor device having a sac through-hole

(75) Inventor: Jiro Miyahara, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY INC., TOKYO (JP)

(21) Appl. No.: 11/700,767

(22) Filed: Feb. 1, 2007

(30) Foreign Application Priority Data
Feb. 2, 2006 (JP) 2006-026095

(51) Int. Cl. H01L 21/302; H01L 21/461

(52) U.S. Cl. 438/689

(57) ABSTRACT

A process for manufacturing a semiconductor device includes the steps of: forming a gate oxide film and a gate electrode on a substrate; forming a SiCN protection film on the gate electrode; depositing an interlayer dielectric film for covering the SiCN protection film; etching the dielectric film in a self-alignment with the SiCN protection film to form a contact hole; and forming a contact plug connected to the surface of the substrate in the contact hole.

### BACKGROUND OF THE INVENTION

1. Field of the Invention

The present invention relates to a semiconductor device having a SAC (Self-Align-Contact) through-hole and, more particularly, to a semiconductor device having a through-hole formed by a SAC technique. The present invention also relates to a method for manufacturing the same.

2. Description of the Related Art

Through-holes are formed penetrating an insulating film overlying a semiconductor substrate. The through-holes each receive therein a plug which connects together an underlying interconnect line formed on the bottom surface of the insulating film and an overlying interconnect line formed on the top surface of the insulation film. In recent years, the design rule of the line-and-space pattern for the interconnect lines has been reduced along with a smaller size of the semiconductor devices. Therefore, the through-holes need to be formed with a high positional accuracy with respect to the fine line-and-space pattern formed on the bottom surface of the insulating film.

A SAC technique is known as a method of manufacturing the through-holes with high positional accuracy. According to the SAC technique, a through-hole is formed in an insulating film by using a interconnection structure formed on the underlying insulating film serving as an etching mask, to thereby expose a part of the underlying interconnect pattern from the overlying interconnect pattern.

The interconnection structure is generally configured by interconnect lines each formed on the base insulating film, a hard mask covering the top surface of each of the interconnect lines, and a sidewall insulating film covering the side surface of each of the interconnect lines and the hard mask. The hard mask and sidewall insulating film serve as a protection film for protecting the interconnect line during the etching for forming the through-holes. A BPSG (Boro-Phospho-Silicate-Glass) film which has a high coverage characteristic for allowing the interconnect lines to be covered without a gap in the space between the interconnect lines is generally used as the insulating film for covering the interconnect lines. In an alternative, a SiO₂ film formed by an HDP-CVD (High Density Plasma Chemical Vapor Deposition) method may be used as the insulating film covering the interconnect lines. A SiN film, with respect to which the above BPSG film or SiO₂ film has a higher etch selectivity, is generally used as the top protection film for the interconnect lines.

A method of forming through-holes by using the SAC technique is disclosed in, e.g., Patent Publication JP-9-213949A.

In recent years, in order to meet a smaller design rule of the semiconductor devices, a further reduction in the width of the interconnection structure itself is required. As the width of the interconnect line itself is reduced, the electric resistance thereof may be increased. For avoiding the higher electric resistance, it may be considered to reduce the thickness of the protection film for the interconnect lines. However, if the thickness of the protection film is excessively reduced, the protection film will be over-etched during etching for forming the through-holes by using the SAC technique. This causes the interconnect lines covered by the protection film to be exposed therefrom, thereby resulting in a short-circuit failure between adjacent interconnect lines.

### SUMMARY OF THE INVENTION

In view of the above problems in the conventional technique, it is an object of the present invention to provide a semiconductor device having a through-hole formed by a SAC technique and, more particularly, a semiconductor device having a smaller-thickness protection film for protecting an interconnect line and capable of preventing the interconnect line from being exposed therefrom.

It is another object of the present invention to provide a method for manufacturing such a semiconductor device.

The present invention provides a semiconductor device including: a first insulating film overlying a substrate and exposing therefrom a conductive material; an interconnect line formed on the first insulating film; a SiCN protection film covering a surface of the interconnect line; a second insulating film formed on the first insulating film and covering the SiCN protection film; and a via-plug penetrating the second insulating film and formed in self-alignment with the protection film, to connect to the conductive material.

The present invention also provides a method for manufacturing a semiconductor device including the steps: forming a first insulating film overlying a substrate and exposing therefrom a conductive material; forming a second interconnect line on the second insulating film; forming a SiCN protection film covering a surface of the second interconnect line; forming a second insulating film on the first insulating film and covering the SiCN protection film; etching the second insulating film in self-alignment with the SiCN protection film to form a through-hole; forming a via-plug within the through-hole, the via-plug connecting to the conductive material.

In accordance with the semiconductor device of the present invention and the semiconductor device manufactured by the method of the present invention, the second insulating film, such as SiO₂ film or BPSG film, can be etched with a higher etch selectivity with respect to the SiCN protection film compared to the etch selectivity with respect to the SiN film used in the conventional technique.

Thus, the SiCN protection film effectively prevents the covered interconnect lines from being exposed from the SiCN protection film, to suppress a short-circuit failure in a higher degree.

The above and other objects, features and advantages of the present invention will be more apparent from the following description, referring to the accompanying drawings.

### BRIEF DESCRIPTION OF THE DRAWINGS

FIG. 1 is a sectional view showing the configuration of a semiconductor device according to an embodiment of the present invention;

FIGS. 2A to 2J are sectional views consecutively showing the fabrication steps of a process for manufacturing the semiconductor device of FIG. 1;

FIG. 3 is a sectional view showing the configuration of a CVD system for use in the process for forming the SiCN film;

FIG. 4 is a graph showing the content ratios in the semiconductor devices of first through third examples of the present invention and a comparative example;

FIG. 5 is a graph showing the relationship between the dielectric constant as well as the etch selectivity and the substrate temperature in the step for forming the SiCN film;

FIG. 6 is a sectional view showing the configuration of a semiconductor device according to a modification of the present embodiment; and

FIGS. 7A and 7B are sectional views showing manufacturing steps of the semiconductor device shown in FIG. 6.

### DETAILED DESCRIPTION OF THE PREFERRED EMBODIMENTS

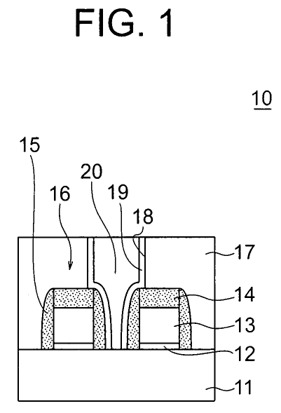

An embodiment of the present invention will be described below in detail with reference to the accompanying drawings. FIG. 1 is a sectional view showing the configuration of a semiconductor device according to an embodiment of the present invention. The semiconductor device, generally designated at numeral 10, is configured as a DRAM (Dynamic Random Access Memory) device and has a semiconductor substrate 11 made of silicon. On the semiconductor substrate 11, a gate oxide film 12, a gate electrode 13 serving as a word line, and a hard mask 14 are consecutively deposited and are each patterned to have a predetermined shape. The gate electrode 13 and hard mask 14 are made of tungsten and SiCN, respectively.

Impurities are introduced in the surface region of the semiconductor substrate 11 at the portion thereof on both sides of the gate electrode 13, to form source/drain regions not shown in the figure. The gate oxide film 12, gate electrode 13 and source/drain regions on both sides of the gate electrode 13 configure a MISFET.

A sidewall insulating film 15 made of SiCN is formed on both side surfaces of the gate oxide film 12, gate electrode 13, and hard mask 14. The hard mask 14 and sidewall insulating film 15 configure a protection film 16 for protecting the gate electrode 13. An interlayer dielectric film 17 made of BPSG is formed on the semiconductor substrate 11 so as to cover the protection film 16. Further, contact holes 18 are formed by anisotropic etching using a SAC technique in which the protection film 16 is used as an etching mask. The contact holes 18 penetrate the interlayer dielectric film 17 and thereby expose therefrom a surface portion of the semiconductor substrate 11.

A sidewall protection film 19 made of SiN is formed on the internal sidewall of the contact holes 18. A polysilicon contact plugs 20 having a side surface covered by the sidewall protection film 19 are received in the contact holes 18. The sidewall protection film 19 is formed for preventing a short-circuit failure which may be involved between adjacent contact plugs 20 due to a possible void formed in the interlayer dielectric film 17 in the space between adjacent contact plugs.

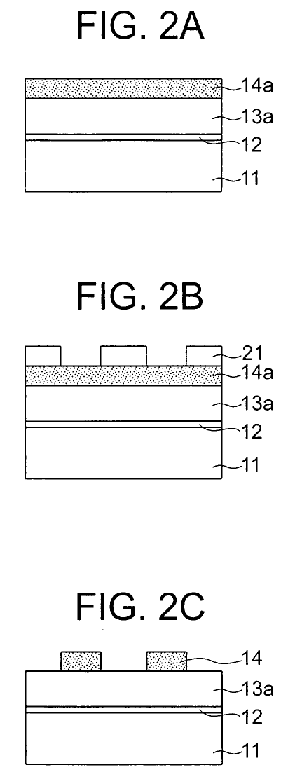

FIGS. 2A to 2J are sectional views consecutively showing fabrication steps of a process for manufacturing the semiconductor device of FIG. 1. Firstly, an ISSG (In-Situ Stream Generation) technique is used to thermally oxidize the surface of the semiconductor substrate 11 to thereby form the gate oxide film 12 thereon. After a PVD (Physical Vapor Deposition) process is conducted to form a tungsten film 13a on the gate oxide film 12, a CVD (Chemical Vapor Deposition) process is used to form a SiCN film 14a on the tungsten film 13a (FIG. 2A). In the formation of the SiCN film 14a, the substrate temperature is set at 550° C.

Subsequently, a known process is used to form, on the SiCN film 14a, a resist mask 21 having openings of a predetermined shape (FIG. 2B). Subsequently, with the resist mask 21 used as a mask, a dry etching process in which a CF₄ gas is used as an etching gas is used to pattern the SiCN film 14a to thereby form the hard mask 14 (FIG. 2C).

Subsequently, with the hard mask 14 used as a mask, a dry etching process in which SF₆ gas is used as an etching gas is used to pattern the tungsten film 13a and gate oxide film 12 to thereby form the gate electrode 13 (FIG. 2D). Further, with the hard mask 14 used as a mask, impurities are implanted into the surface region of the semiconductor substrate 11 at the portion thereof on both sides of the gate electrode 13, to form the source/drain regions. Then, the CVD process is used to form the SiCN film on the entire surface. In the formation of the SiCN film, the substrate temperature is set at 550° C. Further, the SiCN film is etched back to thereby leave the sidewall insulating film 15, which covers the side surfaces of the gate electrode 13 and hard mask 14 (FIG. 2E). The hard mask 14 and sidewall insulating film 15 configure the protection film 16 for protecting the gate electrode 13. Subsequently, a SAP (Sub-Atmospheric Pressure)-CVD process is used to form the interlayer dielectric film 17 made of BPSG on the semiconductor substrate 11 in such a manner as to cover the protection film 16 (FIG. 2F).

Subsequently, a known process is used to form a resist mask 22 having openings of a predetermined shape on the interlayer dielectric film 17 (FIG. 2G). Further, with the resist mask 22 used as a mask, a dry etching in which C₅F₈ gas is used as an etching gas is conducted to etch the interlayer dielectric film 17, to form the contact holes 18 having a bottom exposing therefrom a portion of the semiconductor substrate 11 (FIG. 2H). To form the contact holes 18, a SAC technique is used in which the protection film 16 is used as a mask. Then, an LP (Low Pressure)-CVD process is used to form a SiN film 19a on the bottom surface and sidewall of the contact holes 18 and on the interlayer dielectric film 17 (FIG. 2I). In the formation of the SiN film 19a, the substrate temperature is set at about 700° C.

Subsequently, etch-back is carried out by a dry etching process to remove the SiN film 19a formed on the bottom of the contact holes 18 and on the interlayer dielectric film 17, and leave the sidewall protection film 19 on the sidewall of the contact holes 18 (FIG. 2J). After an LP-CVD process is used to deposit polysilicon on the entire surface including the internal of the contact holes 18, the polysilicon deposited on top of the interlayer dielectric film 17 is removed, and the contact plugs 20 are left in the contact holes 18 (FIG. 1). Further, a bottom electrode of capacitors connected to the top end of the contact plugs 20 is formed, followed by other known steps for completing the process for manufacturing the semiconductor device of FIG. 1.

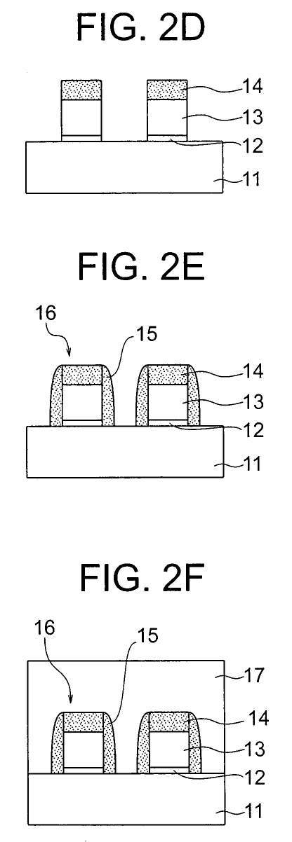

FIG. 3 shows the configuration of a CVD system for use in the fabrication process of the SiCN film shown in FIG. 2A and FIG. 2E. A CVD system 30 is a parallel-plate plasma CVD system which is installed in a chamber 34 and includes a wafer stage 31, on which a wafer (semiconductor substrate) 11 is placed, and a electrode plate 32 for application of a high-frequency power and disposed to oppose the wafer stage 31.

The wafer stage 31 is configured as a bottom electrode and is grounded. The wafer stage 31 incorporates therein a ceramic heater and thereby heats the surface of the wafer stage 31 up to 600° C. The electrode plate 32 is configured as a top electrode and is connected to a terminal of a high-frequency power source 33 for supplying an RF power. The other terminal of the high-frequency power source 33 is grounded. The electrode plate 32 is configured as tube, which is connected to a gas supply source not shown in the figure. A large number of nozzles for discharging a gas are formed on the surface of the electrode plate 32 that opposes the wafer stage 31.

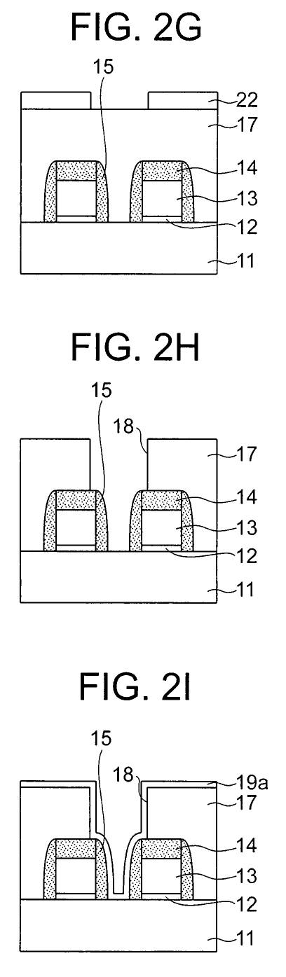

A gas discharge port 35 is provided at the bottom of the chamber 34. A throttle valve 36 and a dry pump 37 are provided in this order along the direction of the gas flow from the gas discharge port 35 of the chamber 34. By controlling the diaphragm of the throttle valve 36 in the state where the dry pump 37 is activated, the pressure in the chamber 34 can be adjusted to a desired value. An arrow in FIG. 4 denotes the direction of gas flow.

In the CVD process for forming the SiCN film by using the CVD system 30 as described above, firstly, a ceramic heater is used to set the temperature of the surface of the wafer stage 31 at 550° C. Then, the wafer 11 is introduced in the chamber 34 and placed on the wafer stage 31, and thereby the substrate temperature of the wafer 11 is maintained at 550° C.

Then, a source gas is supplied through the surface of the electrode plate 32 and, at the same time, an RF power of 600 W is supplied from the high-frequency power source 33. As the source gas, trimethylsilane ((CH₃)₃SiH) and ammonia (NH₃) are supplied at flow rates of 350 sccm and 700 sccm, respectively. In addition, helium is supplied at a flow rate of 800 sccm. The pressure in the chamber 34 is maintained at 3 Torr by the control of the diaphragm of the throttle valve 36. The source gas supplied to the chamber 34 is excited by the RF power into a plasma and subjected to reaction on the wafer 11, thereby forming the SiCN film.

In the process for manufacturing the semiconductor device according to the present embodiment, the protection film 16 is made of SiCN, whereby it is possible to obtain a higher etch selectivity for the etching of the interlayer dielectric film 17 with respect to the SiCN film compared to the case of a conventional protection film made of SiN. As a result, it is possible to prevent the interconnect lines from being exposed while designing a smaller thickness for the protection film 16.

Further, in the present embodiment, the substrate temperature during forming the top SiCN protection film is set at 500° C. or above. This suppresses deterioration of the film quality of the protection film 16 in the subsequent process for forming the SiN film 19a at a substrate temperature of 700° C., with the result that a reduction in the adhesiveness with other films can be suppressed, thereby preventing the peel-off of the protection film 16. Further, the substrate temperature for forming the SiCN film, which is set at 550° C. or lower, reduces the dielectric constant of the resultant protection film 16 down to 5.9 or less, with the result that the dielectric constant of the SiCN protection film 16 is reduced less than that of the SiN, thereby reducing the propagation delay during the signal transfer through the gate electrode 13 or word line. Note that the above type of the gas, pressure, and RF power in the process for forming the SiCN film are merely examples, and the fabrication process may be carried out under other conditions.

In the course of devising the present invention, the present inventor manufactured the semiconductor device by using the substrate temperature for forming the protection film 16 being set at 400° C., which is generally used in the filming process of the SiCN film. In this process, however, it was found that, in the subsequent step for forming the SiN film (FIG. 2I) at a substrate temperature of 700° C., peel-off occurred in the protection film 16.

The cause of the occurrence of peel-off in the protection film 16 is considered as follows. It is known that, after a plasma CVD process is used to form the SiCN film, hydrogen atoms are contained in the film under the condition that the hydrogen atoms are bonded to carbon atoms. The hydrogen atoms contained in the SiCN film escape from the inside of the film in the state of H₂ or H₂O during the high-temperature process, whereby the quality of the SiCN film is deteriorated. As a result, adhesiveness with other films is reduced to cause the peel-off of the film to occur.

In view of the above, the present inventor considered that a reduction in the hydrogen content in the SiCN film may reduce the number of hydrogen atoms to escape from the SiCN film to thereby prevent the deterioration of quality of the SiCN film. It may be considered to raise the temperature for forming the SiCN film in order to reduce the hydrogen content in the SiCN film. Thus, experiments were performed to deposit the SiCN film at a variety of substrate temperatures such as at 400° C. and above.

In the above experiments for the semiconductor device manufacturing process, semiconductor devices were manufactured with the substrate temperature for the SiCN protection film 16 being set at 400° C., 500° C., and 550° C. to obtain first through third examples, respectively. Further, in order to compare with the first through third examples, another semiconductor conductor device in which SiN is used in place of SiCN to form the protection film 16 was manufactured as a comparative example. The process for forming the SiN film in the semiconductor device of the comparative example was performed out under a condition similar to the conditions in the above examples for the SiCN film 19a. The content ratios of the elements in the resultant protection films were measured for the resultant semiconductor devices of the first through third examples and comparative example. The results are shown in Table 1 and FIG. 4.

TABLE 1

Content
ratios (%)

| | Si | C | N | H |
|---|---|---|---|---|
| Example 1 (400° C.) | 24 | 20 | 21 | 35 |
| Example 2 (500° C.) | 24 | 19 | 28 | 29 |
| Example 3 (550° C.) | 25 | 19 | 28 | 28 |
| Comparative | 31 | 0 | 44 | 25 |
| Example | | | | |

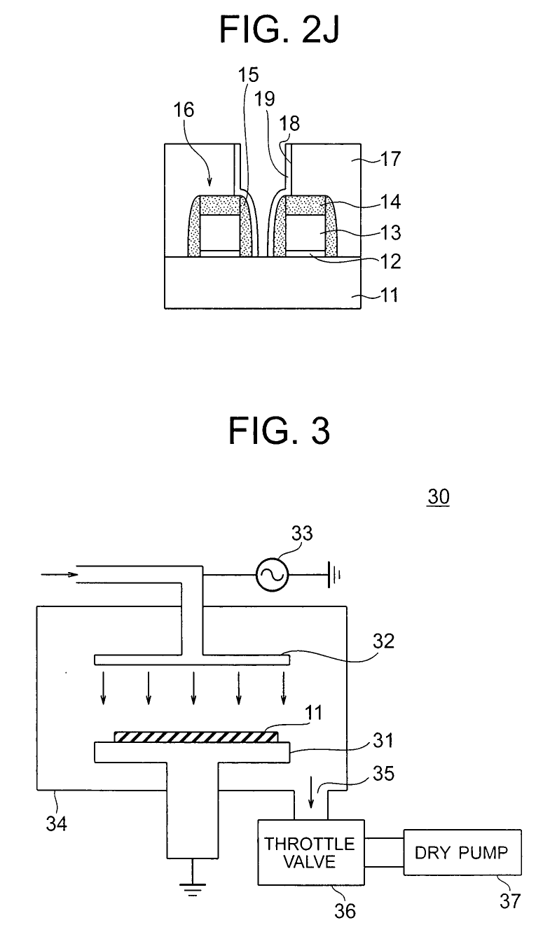

As will be understood from Table 1 and FIG. 5, along with the rise of the substrate temperature for forming the SiCN film, the hydrogen (H) content is reduced. That is, it is estimated that, along with the rise of the substrate temperature, the degree of the film quality deterioration is reduced in the subsequent process for forming the SiN film 19a at a substrate temperature of 700° C. Here, presence/absence of the peel-off of the protection film 16 was examined for the semiconductor devices of first through third examples. The peel-off occurred in the semiconductor device of the first example, whereas the peel-off did not occur in the semiconductor devices of the second and third examples. As a result, it was concluded that the peel-off can be prevented by setting the substrate temperature for forming the SiCN film up to 500° C. or above.

Further, the present inventor examined the dielectric constant those films and the etch selectivity of the SiO₂ film with respect to the SiCN film and SiN film for the semiconductor devices of the first through third examples and comparative example. The dielectric constant and etch selectivity of the interlevel dielectric film with respect to the SiN film are shown in FIG. 5 at the left-side ordinate and right-side ordinate, respectively. The abscissa denotes the substrate temperature for depositing the SiCN film. In FIG. 5, graphs (i) and (ii) show the change in the dielectric constant and etch selectivity, respectively, for the SiCN film of the first through third examples associated with the temperature change, exhibiting approximately straight lines.

As will be understood from FIG. 5, the dielectric constant of the SiCN film is increased along with the rise in the filming temp for the SiCN film. The increase in the dielectric constant leads to an increase in the propagation delay during the signal transfer along the interconnect lines. Thus, it is desirable to reduce the dielectric constant for the protection film as much as possible. In this respect, FIG. 5 shows that, in the range where the filming temperature is 550° C. or below, the dielectric constant of the SiCN film is reduced down to a value considerably lower than 5.9 which is the dielectric constant of the SiN. Therefore, by setting the filming temperature for the SiCN film to 550° C. or lower, the increase in the dielectric constant of the protection film 16 is suppressed.

Further, the etch selectivity of the SiCN film is increased along with a rise in the filming temperature for the SiCN film. The etch selectivity of the SiN film is about 10, while the etch selectivity of the SiCN film is 12 or above at a filming temperature of 400° C. or above. Thus, it is possible to obtain an etch selectivity in the case of SiCN film much higher than that in the case of the SiN film. Note that the etch selectivity of the BPSG film with respect to the SiCN film or SiN film has a substantially same tendency for the etch selectivity of the SiO₂ film.

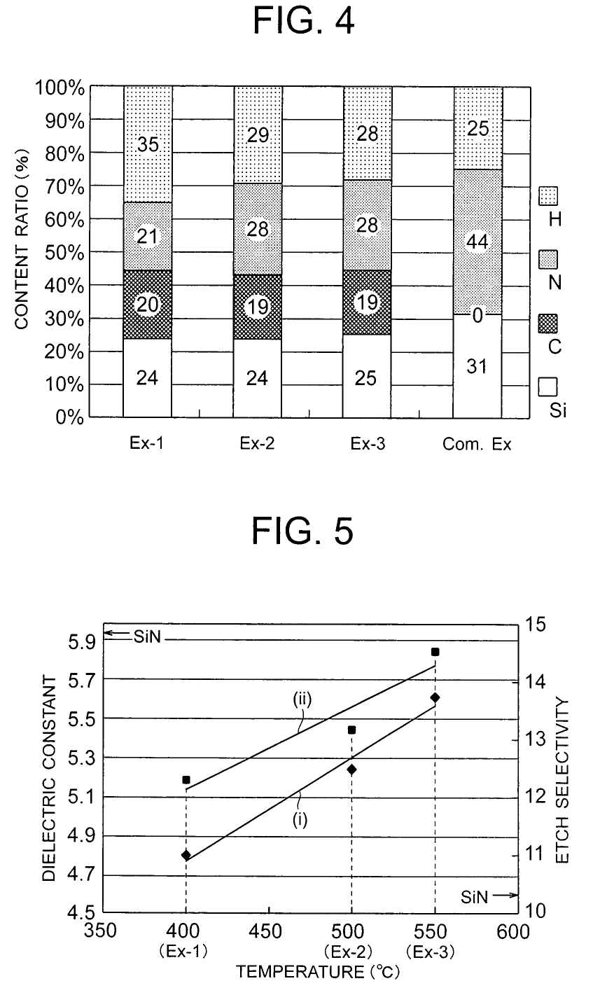

Although the semiconductor device according to the above embodiment has the contact holes in which the contact plugs in contact with the semiconductor substrate are received, the present invention can also be applied to a semiconductor device having a through-hole provided with a via-plug connecting interconnect lines together. FIG. 6 is a sectional view showing the configuration of a semiconductor device according to a modification of the above embodiment. The semiconductor device 40 has a semiconductor substrate (not shown) and an interlayer dielectric film 41 formed above the semiconductor substrate. A contact hole 42 penetrates the interlayer dielectric film 41, and a polysilicon contact plug 44 having a sidewall covered with a sidewall protection film 43 is received in the contact holes 42.

An interconnection structure having an interconnect line 45, a protection film 48 including a SiCN top protection film (hard mask) 46 and a SiCN sidewall insulating film 47 is formed on the interlayer dielectric film 41. Another interlayer dielectric film 49 is formed on the interlayer dielectric film 41 so as to cover the interconnection structure. Each of the interlayer dielectric films 41 and 49 is made of SiO₂. In the interconnection structure, the interconnect line 45 is directly formed on the interlayer dielectric film 41 without an intervention of other insulating films and covered by the protection film 48. The interconnect line 45 is configured as a bit line. A through-hole 50 is formed in the interlayer dielectric film 49 using a SAC technique in which the protection film 48 is used as a mask. A via-plug 52 having a sidewall covered by a sidewall protection film 51 is formed in the through-hole 50.

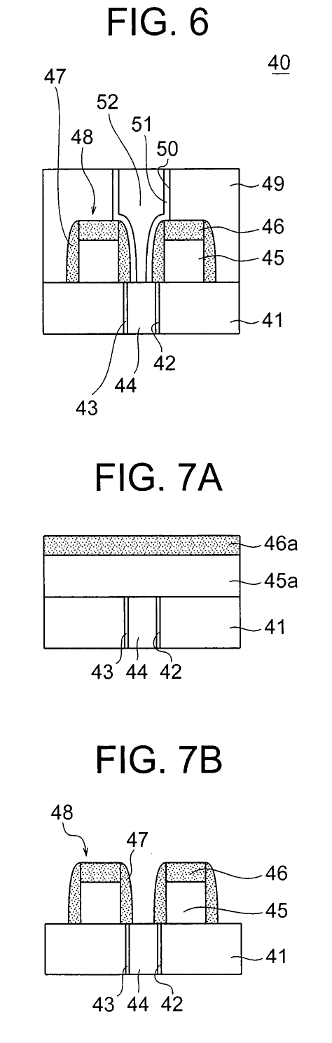

A process for In manufacturing the semiconductor device 40 of FIG. 6 is shown in FIGS. 7A and 7B. A tungsten layer 45a is directly formed on an interlayer dielectric film 41, as shown in FIG. 7, followed by forming a SiCN film 46a on the tungsten layer 45a and etching the same together with the tungsten layer 45a to form interconnect lines 45 and associated SiCN hard mask 46. Further, as shown in FIG. 7B, the SiCN sidewall insulating film 47 is formed on the sidewalls of the interconnect lines 45 and the SiCN hard mask 46. In the filming process for the interlayer dielectric film 49 shown in FIG. 6, an HDP-CVD process is used.

As described with reference to the embodiment and the modification, the SiCN protection film covering the surface of the interconnect line effectively protects the interconnect line against the etching of the SiCN protection film during etching the overlying interlevel dielectric film.

It is preferable in the semiconductor device of the present invention that the SiCN film have a dielectric constant of 5.9 or below.

The conductive material exposed from the first insulating film may be a portion of a semiconductor substrate, or may be a plug connected to another interconnect line or a semiconductor substrate. The plug may be a contact plug or a via-plug.

It is preferable in the method of the present invention that the SiCN protection film forming step include the step of depositing SiCN at a substrate temperature between 500 degrees C. and 550 degrees C.

It is also preferable that the process further includes the step of forming a sidewall protection film covering an internal sidewall of the through-hole exposing therefrom the conductive material.

Although the present invention has been described with reference to the preferred embodiment, the semiconductor device according to the present invention and its manufacturing process are not limited to the above embodiment, and a semiconductor device and its manufacturing process obtained by making various modifications and changes in the configurations of the above-described embodiment are also included in the scope of the present invention.

What is claimed is:

1. A semiconductor device comprising the steps of:
a first insulating film exposing therefrom a conductive material overlying a substrate;
an interconnect line formed on said first insulating film;
a SiCN protection film covering a surface of said interconnect line;
a second insulating film formed on said first insulating film and covering said SiCN protection film; and
a via-plug penetrating said second insulating film and formed in self-alignment with said protection film, to connect to said conductive material.

2. The semiconductor device according to claim 1, wherein said SiCN film has a dielectric constant of 5.9 or less.

3. The semiconductor device according to claim 1, wherein said conductive material is connected to another interconnect line.

4. The semiconductor device according to claim 1, wherein said conductive material is connected to a semiconductor substrate.

5. A method for manufacturing a semiconductor device comprising the steps:
forming a first insulating film overlying a substrate and exposing therefrom a conductive material;
forming a second interconnect line on said second insulating film;
forming a SiCN protection film covering a surface of said second interconnect line;
forming a second insulating film on said first insulating film and covering said SiCN protection film;
etching said second insulating film in self-alignment with said SiCN protection film to form a through-hole;
forming a via-plug within said through-hole, said via-plug connecting to said conductive material.

6. The method according to claim 5, said SiCN protection film forming step includes the step of depositing SiCN at a substrate temperature between 500 degrees C. and 550 degrees C.

7. The method according to claim 5, wherein said SiCN film has a dielectric constant of 5.9 or less.

8. The method according to claim 5, further comprising the step of forming a sidewall protection film covering an internal sidewall of said through-hole.

9. The method according to claim 5, wherein said conductive material is connected to another interconnect line.

10. The method according to claim 5, wherein said conductive material is connected to said semiconductor substrate.
